(19) United States
(12) Patent Application Publication
(10) Pub. No.: US 2023/0421110 A1
(43) Pub. Date: Dec. 28, 2023

(54) ANALOG PREDISTORTION (APD) SYSTEM FOR POWER AMPLIFIERS

(71) Applicant: Qorvo US, Inc., Greensboro, NC (US)

(72) Inventors: George Maxim, Saratoga, CA (US); Nadim Khlat, Cugnaux (FR); Baker Scott, San Jose, CA (US)

(21) Appl. No.: 18/203,831

(22) Filed: May 31, 2023

Related U.S. Application Data
(60) Provisional application No. 63/381,476, filed on Oct. 28, 2022.
(60) Provisional application No. 63/354,286, filed on Jun. 22, 2022.

(51) Int. Cl. H03F 1/32; H03F 1/02; H03F 3/21

(52) U.S. Cl. CPC H03F 1/3241; H03F 1/0288; H03F 3/211; H03F 2201/3224; H04B 2001/0425

(57) ABSTRACT

An analog predistortion system for power amplifiers is disclosed. In one aspect, the system may apply analog predistortion to offset memory effects that may occur as a function of frequencies that operate faster than time constants of the related circuits. In a particular aspect, the analog predistortion is applied at least to a phase of the signal to be amplified, but may also be applied to a gain of the signal to be amplified. When such memory focused analog predistortion is combined with memoryless or low depth memory digital predistortion, overall linearity and performance of the power amplifier is improved.

### PRIORITY APPLICATIONS

The present application is related to U.S. Provisional Patent Application Ser. No. 63/385,343 filed on Nov. 29, 2022, and entitled “SUPPLY VOLTAGE BASED ANALOG PREDISTORTION (APD) CIRCUIT FOR POWER AMPLIFIER,” the contents of which is incorporated herein by reference in its entirety.

The present application is related to U.S. Provisional Patent Application Ser. No. 63/354,286 filed on Jun. 22, 2022, and entitled “DIRECT ANALOG MEMORY PRE-DISTORTION USING WEIGHTED SUMMATION OF VARIABLE VARACTOR COMPRESSED AVERAGING FOR PA LINEARIZATION,” the contents of which is incorporated herein by reference in its entirety.

### BACKGROUND

### I. Field of the Disclosure

The technology of the disclosure relates generally to correcting distortion in power amplifiers.

### II. Background

Computing devices abound in modern society, and more particularly, mobile communication devices have become increasingly common. The prevalence of these mobile communication devices is driven in part by the many functions that are now enabled on such devices. Increased processing capabilities in such devices means that mobile communication devices have evolved from pure communication tools into sophisticated mobile entertainment centers, thus enabling enhanced user experiences. With the advent of the myriad functions available to such devices, there has been increased pressure to find ways to move more data to and from the devices. Such pressure has resulted in evolutions in wireless standards with a trend toward using higher frequencies. These higher frequencies place new demands on power amplifiers used in the transceivers. The new demands on the transceivers open the opportunity for innovation.

### SUMMARY

Aspects disclosed in the detailed description include an analog predistortion (APD) system for power amplifiers. In particular, exemplary aspects are designed to provide APD to offset memory effects that may occur as a function of frequencies that operate faster than time constants of the related circuits. In a particular aspect, the APD is applied at least to a phase portion of a signal to be amplified, but may also be applied to a gain portion of the signal to be amplified. When such memory-focused APD is combined with memoryless or low-depth memory digital predistortion (DPD), overall linearity and performance of the power amplifier is improved.

In this regard in one aspect, a power amplifier is disclosed. The power amplifier comprises an amplifying stage subjected to memory distortion. The power amplifier also comprises an APD circuit coupled to the amplifying stage and configured to predistort a signal to offset the memory distortion.

In another aspect, a transceiver is disclosed. The transceiver comprises a baseband processor (BBP) comprising a DPD circuit configured to apply memoryless DPD to a signal to be transmitted. The transceiver also comprises a power amplifier coupled to the BBP and configured to receive the signal to be transmitted after the DPD circuit has applied the memoryless DPD. The power amplifier comprises an amplifying stage subjected to memory distortion. The power amplifier also comprises an APD circuit coupled to the amplifying stage and configured to predistort the signal to be transmitted to offset the memory distortion.

### BRIEF DESCRIPTION OF THE DRAWINGS

FIG. 1A is a block diagram of an exemplary transceiver system with a baseband processor (BBP) to provide memoryless digital predistortion (DPD) for a power amplifier that uses analog predistortion (APD) on a phase portion of a signal for memory-induced distortion;

FIG. 1B is a block diagram of an exemplary transceiver system with a BBP to provide memoryless DPD for a power amplifier that uses APD on a phase portion and a gain portion of a signal for memory-induced distortion;

FIG. 2A is a block diagram of an exemplary transceiver system with a BBP to provide memoryless DPD and low-depth memory DPD for a power amplifier that uses APD on a phase portion of a signal for memory-induced distortion;

FIG. 2B is a block diagram of an exemplary transceiver system with a BBP to provide memoryless DPD and low-depth memory DPD for a power amplifier that uses APD on a phase portion and a gain portion of a signal for memory-induced distortion;

FIG. 3 is a graph of a capacitance as a function of voltage relative to an input voltage for a varactor that may be used to assist in providing APD;

FIG. 4 is a block diagram of a transceiver system with additional details for an APD applied to a phase portion of the signal to be amplified by the power amplifier;

FIG. 5 is a block diagram of a transceiver system with a hybrid power amplifier that may have additional feedback to control the APD;

FIG. 6 is a block diagram of a transceiver system with a quadrature power amplifier that may apply APD to both phase and gain;

FIG. 7 is a block diagram of a transceiver system with a quadrature power amplifier that uses cross coupling to apply APD to both phase and gain;

FIG. 8 is a block diagram of a transceiver system with a Doherty power amplifier that applies APD; and

FIG. 9 is a block diagram of an exemplary mobile computing device which may include the transceiver systems of the present disclosure.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and similarly, a second element could be termed a first element without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Aspects disclosed in the detailed description include an analog predistortion (APD) system for power amplifiers. In particular, exemplary aspects are designed to provide APD to offset memory effects that may occur as a function of frequencies that operate faster than time constants of the related circuits. In a particular aspect, the APD is applied at least to a phase portion of a signal to be amplified, but may also be applied to a gain portion of the signal to be amplified. When such memory-focused APD is combined with memoryless or low-depth memory digital predistortion (DPD), overall linearity and performance of the power amplifier is improved.

The advent of the higher frequencies associated with evolving cellular and wireless communication standards has posed challenges for power amplifiers. Specifically, in many power amplifiers operating at high frequencies and wide modulation bands, the circuits that form the power amplifiers may have time constants which are loosely equivalent to the modulation band. The result of this proximate equivalence is that the circuit may not fully settle into stable operation before a change is made. This lack of settling means that a power amplifier will have some distortion which is a function of its previous state. This quality is sometimes referred to as “memory.” It should be appreciated that memory distortion is primarily expressed as phase distortion although there can be gain distortion that is a function of memory. Likewise, memory distortion will be a larger percentage of small signals compared to large signals even if the absolute amount of distortion remains the same. As a general rule, to avoid memory effects, an operating frequency must be four to five times a modulation bandwidth. Thus, if a modulation bandwidth is in the 200 Megahertz (MHz) range, the operating frequency would need to be around 1 Gigahertz (Ghz). Such operating bandwidths are hard to achieve efficiently and cost effectively. A compromise that has historically been acceptable is to accept memory distortion and plan on correcting this distortion using digital predistortion (DPD).

Unfortunately, while DPD for memoryless distortion is readily implemented with a polynomial having a reasonable amount of coefficients, efforts to use DPD to address memory distortion increases the complexity by an order of magnitude. The polynomial has lots of coefficients, each of which must be calibrated for every element of the power amplifier and every mode in which each of those elements may operate. This approach dramatically increases the cost and complexity of the DPD and has become a proverbial nightmare for transceiver designers.

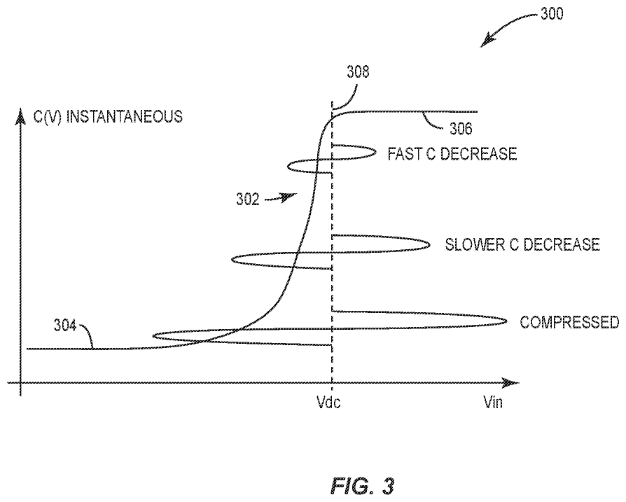

Exemplary aspects of the present disclosure provide an analog predistortion (APD) circuit in the power amplifier that is focused on removing memory distortion greatly simplifying the burden placed on a baseband processor (BBP) and its DPD circuitry. In particular, a varactor whose capacitance is a function of voltage and is generally s-shaped is well suited for use in exemplary aspects as better explained below with reference to FIG. 3.

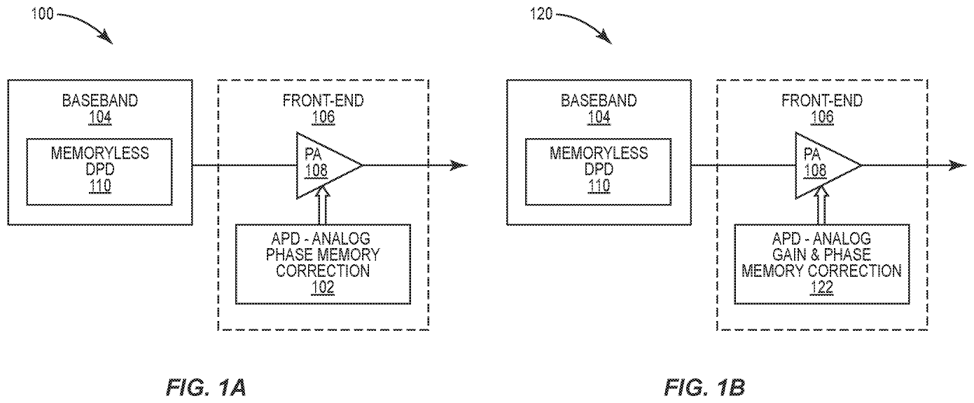

FIG. 1A introduces a transceiver system 100 with an APD circuit 102 in its simplest form. More specifically, the transceiver system 100 includes a BBP 104 coupled to a front end module (FEM) 106 containing a power amplifier 108. The BBP 104 may include a DPD circuit 110 that is memoryless. That is, the DPD circuit 110 does not provide any predistortion for the purpose of offsetting distortion caused by previous states of the power amplifier 108 or its constituent elements. The APD circuit 102 is present in the FEM 106 and distorts a signal to be transmitted based on previous states of the power amplifier 108 (i.e., the APD circuit 102 provides memory correction). Further, because most of the memory distortion is phase distortion, the APD circuit 102 just corrects the phase.

Similarly, FIG. 1B introduces a slightly more complex transceiver system 120 with many of the same elements as the transceiver system 100 of FIG. 1A, but instead of the APD circuit 102, an APD circuit 122 is provided which provides both phase and gain memory correction. While it is possible to provide an APD circuit that only provides gain memory correction, the improvements provided by such a structure have to date proven to be insufficient to justify the expense of such an approach.

While the simplest approach is keeping the DPD circuit memoryless, the present disclosure is not limited to this approach, and a DPD circuit may be used which performs “low-depth” memory DPD. As used herein, “low-depth” memory DPD is DPD that only corrects for the last one to five cycles of memory. While such low-depth memory DPD is more complex than memoryless DPD, the burden on the BBP is not so egregious that it is cost prohibitive. Note that this combined approach may be less efficient as there may be tension between the two memory corrections (e.g., the APD circuit may overcompensate leading to adjustments by the DPD circuit leading to adjustments by the APD circuit, and so on).

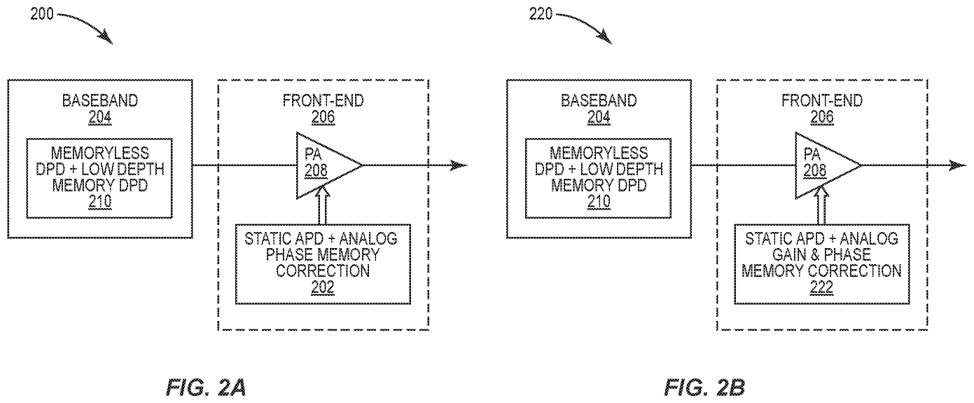

Thus, in FIGS. 2A and 2B, two transceiver systems 200 and 220 are illustrated. The transceiver system 200 of FIG. 2A includes an APD circuit 202 that operates on higher-depth memory correction. A BBP 204 is coupled to an FEM 206 containing a power amplifier 208. The BBP 204 may include a DPD circuit 210 that provides memoryless DPD as well as low-depth memory DPD. The APD circuit 202 is present in the FEM 206 and distorts a signal to be transmitted based on previous states (high depth) of the power amplifier 208. Further, because most of the memory distortion is phase distortion, the APD circuit 202 just corrects the phase.

The more complex transceiver system 220 of FIG. 2B has many of the same elements as the transceiver system 200 of FIG. 2A, but instead of the APD circuit 202, an APD circuit 222 is provided which provides both phase and gain high-depth memory correction. Again, while it is possible to provide an APD circuit that only provides gain memory correction, the improvements provided by such a structure have to date proven to be insufficient to justify the expense of such an approach.

The APD circuits 102, 122, 202, 222 may be needed to address prior signal history. This need may be addressed by using a plurality of delay paths in parallel with each path having prescribed delay stages to provide memory followed by correction circuits. The correction circuits, particularly the phase correction circuit, may exhibit some compressing characteristic that approximately matches a compression of the phase memory distortion of the main power amplifier distorter (i.e., an output stage). A varactor with an s-shaped capacitance function provides the desired compressing characteristic as illustrated in FIG. 3.

Specifically, FIG. 3 illustrates a graph 300 where C(V) is plotted against Vin. A capacitance 302 is monotonically increasing with a flat region 304 and a flat region 306. A bias point 308 is selected proximate the flat region 306 so that desired capacitances are provided based on the changes in Vin.

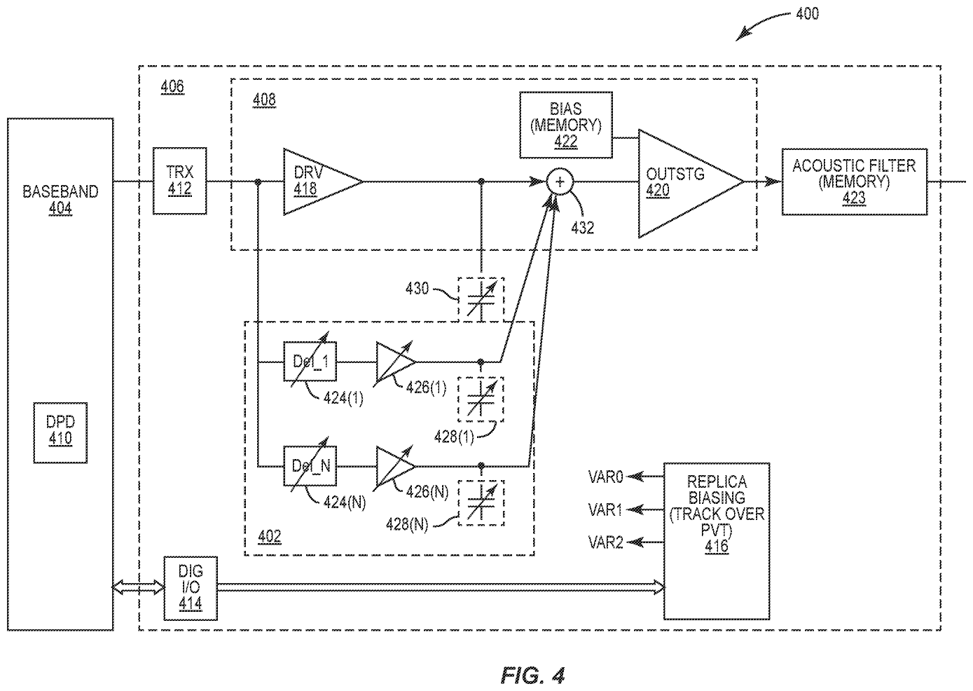

When the varactors having the C(V) characteristic of the graph 300 are used with delay lines, memory distortion may be corrected as illustrated in FIG. 4. More specifically, FIG. 4 illustrates a transceiver system 400 having an APD circuit 402 and a BBP 404 coupled to an FEM 406 containing a power amplifier 408. The BBP 404 may include a DPD circuit 410. The FEM 406 may further include other transceiver circuitry 412 that may upconvert frequencies of signals to be transmitted that are received from the BBP 404, provide filtering, or the like. The FEM 406 may further include a digital input/output (I/O) circuit 414 that may act as a control circuit and receives control signals or mode signals from the BBP 404 and/or control a bias circuit 416 that adjusts bias signals to the APD circuit 402 based on temperature or the like and may be calibrated for process variations.

The power amplifier 408 may include one or more amplifying stages subject to memory based distortion such as a driver stage 418 and an output stage 420. Additional stages (not shown) may be provided without departing from the present disclosure. Likewise, the stages 418, 420 may be cascoded transistors or the like and need not be monolithic. A bias circuit 422 may provide a bias signal to the output stage 420. Additionally, a filter 423 may be present at an output of the output stage 420. The filter 423 and the bias circuit 422 that may be sources of memory distortion.

The APD circuit 402 includes a plurality of delay paths equal to a desired memory depth. Each path may include a respective delay circuit 424(1)-424(N) followed by an amplifier 426(1)-426(N). Note that the amplifiers 426(1)-426(N) are approximately an order of magnitude smaller than the driver stage 418 and even smaller compared to the output stage 420. Current output by the amplifiers 426(1)-426(N) is modified by respective varactors 428(1)-428(N). An additional varactor 430 may be present at an output of the driver stage 418. Currents from the amplifiers 426(1)-426(N) and the driver stage 418 are summed at a summation node 432. As noted, the varactors 428(1)-428(N) and 430 may be controlled by bias signals from the bias circuit 416.

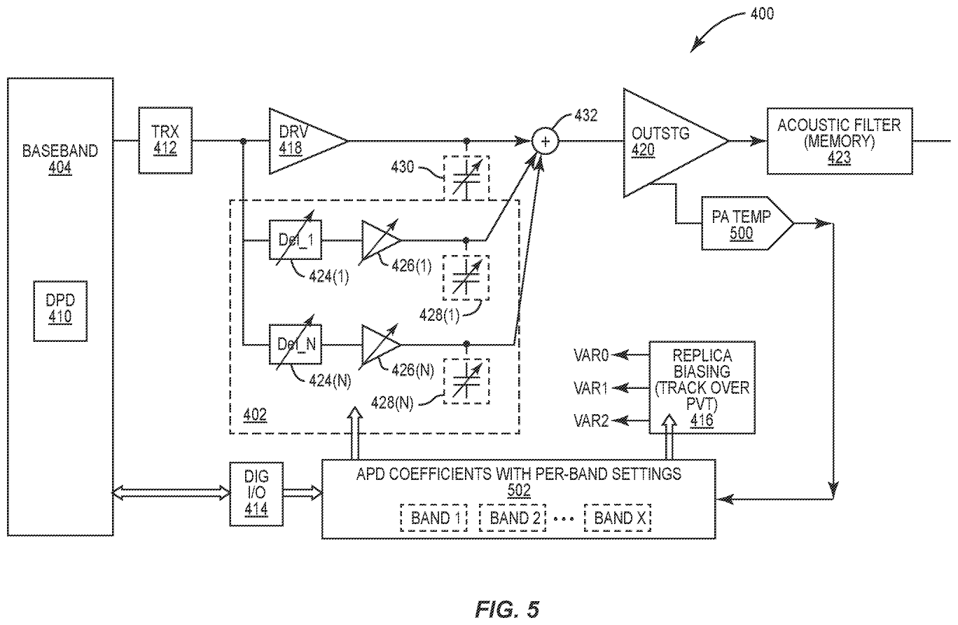

It is possible that the power amplifier 408 may be a hybrid power amplifier with the driver stage 418 implemented as a complementary metal oxide semiconductor (CMOS) structure and the output stage 420 implemented as a bipolar structure using a material such as gallium arsenide (GaAs) as seen in FIG. 5. This arrangement may allow a temperature sensor 500 to be added in the GaAs material which tracks the temperature of the output stage 420. This information may be provided to a control circuit 502 that uses the temperature and other information such as mode information to select coefficients for the bias circuit 416.

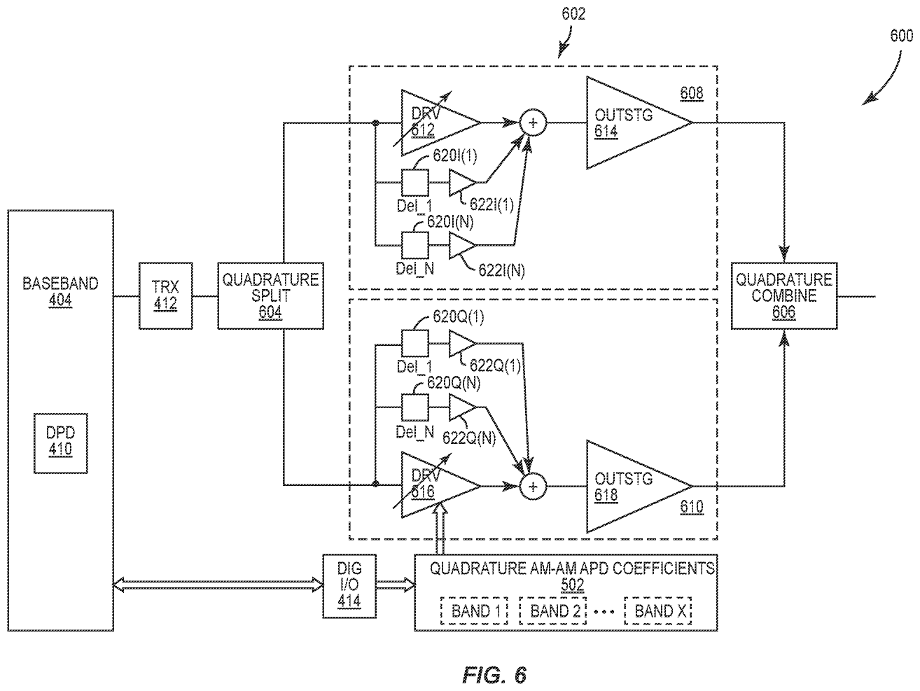

The above discussion has focused just on phase APD. It can be challenging to implement APD for gain in a single-ended system. However, in a quadrature system where there is an I-path and a Q-path, where the I-path corresponds to the gain path and the Q-path corresponds to the phase path, such gain-based APD is more readily effected. This situation is illustrated in FIG. 6.

In this regard, a transceiver system 600 may include a quadrature power amplifier 602 having a splitter circuit 604 and a combiner circuit 606. The power amplifier 602 may further have an I-path 608 and a Q-path 610. The I-path 608 may include a driver stage 612 and an output stage 614 while the Q-path 610 has its own driver stage 616 and output stage 618. Each path 608 and 610 may have its own delay circuits 6201(1)-620I(N) and 620Q(1)-620Q(N), varactors (not shown), and amplifiers 6221(1)-6221(N) and 622Q(1)-622Q(N).

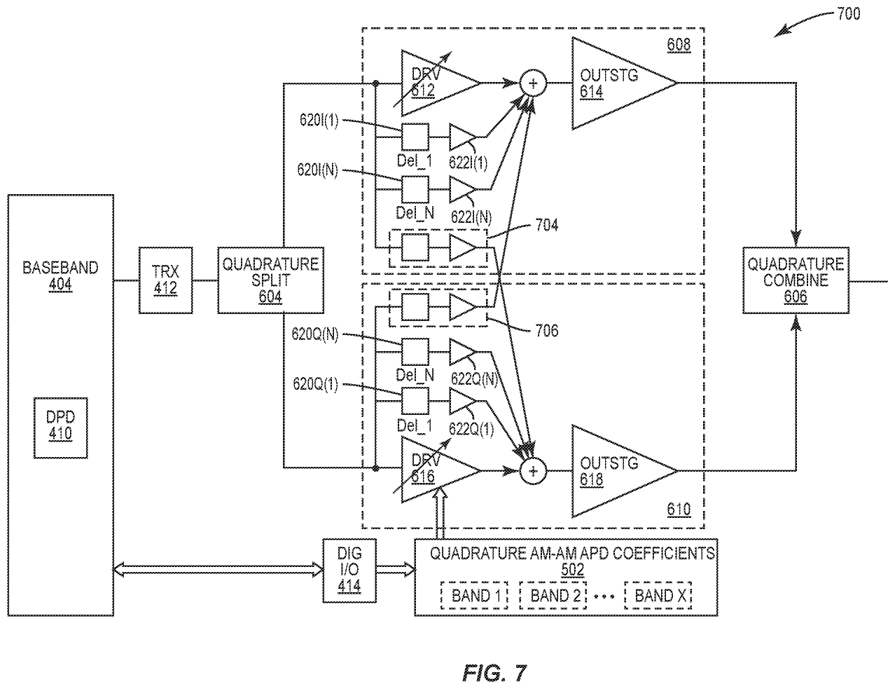

As another option, the APD circuit may cross couple across the I-Q split as better seen in FIG. 7. A transceiver system 700 may include a quadrature power amplifier 702 having a splitter circuit 604 and a combiner circuit 606. The power amplifier 702 may further have an I-path 608 and a Q-path 610. The I-path 608 may include a driver stage 612 and an output stage 614 while the Q-path 610 has its own driver stage 616 and output stage 618. In addition to the delay circuits 6201(1)-620I(N) and 620Q(1)-620Q(N), varactors (not shown), and amplifiers 6221(1)-622I(N) and 622Q(1)-622Q(N), the power amplifier 702 may include an I-Q crosspath 704 in the I-path 608 and a Q-I crosspath 706 in the Q-path 610. The I-Q crosspath 704 includes a delay circuit and an amplifier and applies a small gain adjustment to the Q-path 610. Conversely, the Q-I crosspath 706 includes a delay circuit and an amplifier and applies a small phase adjustment to the I-path 608.

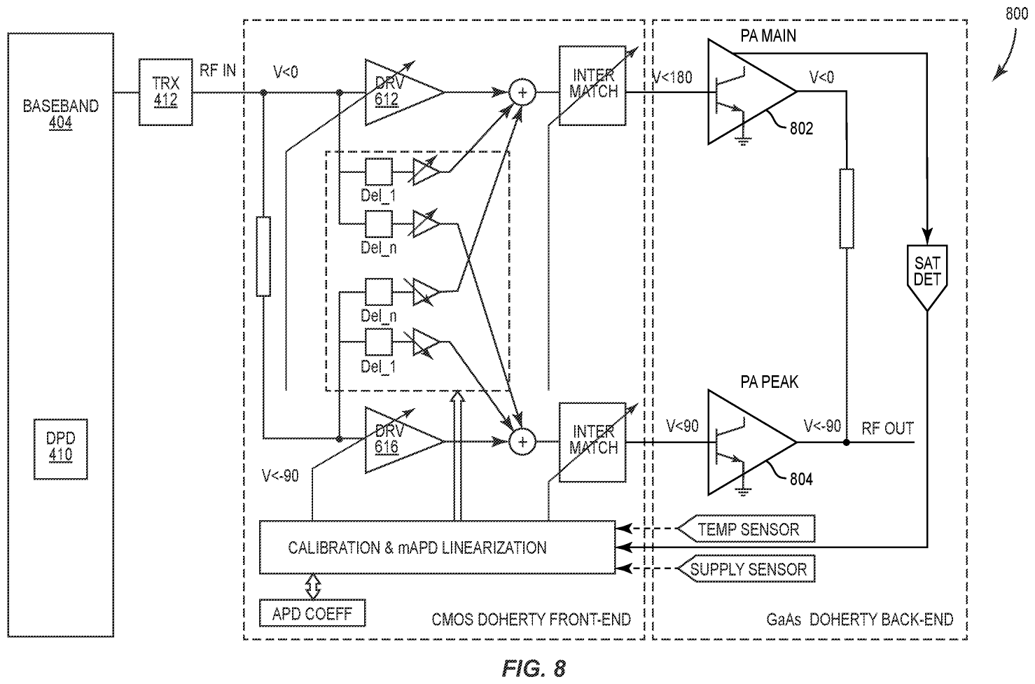

Aspects of the present disclosure may also be used with a power amplifier 800 having a Doherty amplifier as illustrated in FIG. 8. Many elements are the same, but the APD circuit is applied more selectively depending on whether the main path with the main power amplifier 802 is solely active or if a peaking amplifier 804 has been turned on.

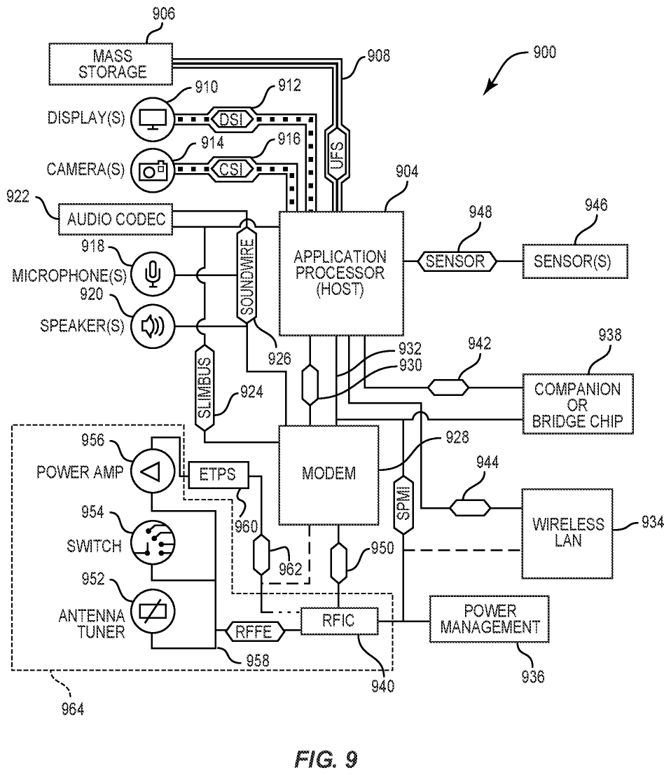

The teachings of the present disclosure are well suited for use in a mobile terminal. In this regard, FIG. 9 is a system-level block diagram of an exemplary mobile terminal 900 such as a smart phone, mobile computing device tablet, or the like. The mobile terminal 900 includes an application processor 904 (sometimes referred to as a host) that communicates with a mass storage element 906 through a universal flash storage (UFS) bus 908. The application processor 904 may further be connected to a display 910 through a display serial interface (DSI) bus 912 and a camera 914 through a camera serial interface (CSI) bus 916. Various audio elements such as a microphone 918, a speaker 920, and an audio codec 922 may be coupled to the application processor 904 through a serial low-power interchip multimedia bus (SLIMbus) 924. Additionally, the audio elements may communicate with each other through a SOUNDWIRE bus 926. A modem 928 may also be coupled to the SLIMbus 924 and/or the SOUNDWIRE bus 926. The modem 928 may further be connected to the application processor 904 through a peripheral component interconnect (PCI) or PCI express (PCIe) bus 930 and/or a system power management interface (SPMI) bus 932.

With continued reference to FIG. 9, the SPMI bus 932 may also be coupled to a local area network (LAN or WLAN) IC (LAN IC or WLAN IC) 934, a power management integrated circuit (PMIC) 936, a companion IC (sometimes referred to as a bridge chip) 938, and a radio frequency IC (RFIC) 940. It should be appreciated that separate PCI buses 942 and 944 may also couple the application processor 904 to the companion IC 938 and the WLAN IC 934. The application processor 904 may further be connected to sensors 946 through a sensor bus 948. The modem 928 and the RFIC 940 may communicate using a bus 950.

With continued reference to FIG. 9, the RFIC 940 may couple to one or more RFFE elements, such as an antenna tuner 952, a switch 954, and a power amplifier 956 through a radio frequency front end (RFFE) bus 958. Additionally, the RFIC 940 may couple to an envelope tracking power supply (ETPS) 960 through a bus 962, and the ETPS 960 may communicate with the power amplifier 956. The power amplifier 956 may be modified by the APD circuits of the present disclosure. Collectively, the RFFE, elements, including the RFIC 940, may be considered an RFFE system 964. It should be appreciated that the RFFE bus 958 may be formed from a clock line and a data line (not illustrated).

It is also noted that the operational steps described in any of the exemplary aspects herein are described to provide examples and discussion. The operations described may be performed in numerous different sequences other than the illustrated sequences. Furthermore, operations described in a single operational step may actually be performed in a number of different steps. Additionally, one or more operational steps discussed in the exemplary aspects may be combined. It is to be understood that the operational steps illustrated in the flowchart diagrams may be subject to numerous different modifications as will be readily apparent to one of skill in the art. Those of skill in the art will also understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

The previous description of the disclosure is provided to enable any person skilled in the art to make or use the disclosure. Various modifications to the disclosure will be readily apparent to those skilled in the art, and the generic principles defined herein may be applied to other variations. Thus, the disclosure is not intended to be limited to the examples and designs described herein but is to be accorded the widest scope consistent with the principles and novel features disclosed herein.

What is claimed is:

1. A power amplifier comprising:
an amplifying stage subjected to memory distortion; and
an analog predistortion (APD) circuit coupled to the amplifying stage and configured to predistort a signal to offset the memory distortion.

2. The power amplifier of claim 1, wherein the APD circuit is configured to predistort a phase portion of the signal to offset the memory distortion.

3. The power amplifier of claim 1, wherein the APD circuit is configured to predistort a phase portion and a gain portion of the signal to offset the memory distortion.

4. The power amplifier of claim 1, wherein the amplifying stage comprises a driver stage and an output stage.

5. The power amplifier of claim 4, wherein the driver stage comprises a complementary metal oxide semiconductor (CMOS) structure and the output stage comprises a bipolar structure.

6. The power amplifier of claim 1, wherein the amplifying stage comprises a quadrature power amplifier having a gain path and a phase path.

7. The power amplifier of claim 1, wherein the APD circuit comprises a delay circuit and an amplifier.

8. The power amplifier of claim 7, wherein the APD circuit further comprises a varactor.

9. The power amplifier of claim 1, wherein the APD circuit comprises a plurality of delay paths each comprising a delay circuit, an amplifier, and a varactor.

10. The power amplifier of claim 1, wherein the amplifying stage comprises a Doherty amplifier.

11. A transceiver comprising:
a baseband processor (BBP) comprising a digital predistortion (DPD) circuit configured to apply memoryless DPD to a signal to be transmitted; and
a power amplifier coupled to the BBP and configured to receive the signal to be transmitted after the DPD circuit has applied the memoryless DPD,
wherein the power amplifier comprises:
an amplifying stage subjected to memory distortion; and
an analog predistortion (APD) circuit coupled to the amplifying stage and configured to predistort the signal to be transmitted to offset the memory distortion.

12. The transceiver of claim 11, wherein the DPD circuit is further configured to apply a low-depth memory DPD to the signal to be transmitted.

13. The transceiver of claim 11, wherein the APD circuit is configured to predistort a phase portion of the signal to be transmitted to offset the memory distortion.

14. The transceiver of claim 11, wherein the APD circuit is configured to predistort a phase portion and a gain portion of the signal to be transmitted to offset the memory distortion.

15. The transceiver of claim 11, wherein the amplifying stage comprises a driver stage and an output stage.

16. The transceiver of claim 15, wherein the driver stage comprises a complementary metal oxide semiconductor (CMOS) structure and the output stage comprises a bipolar structure.

17. The transceiver of claim 11, wherein the amplifying stage comprises a quadrature power amplifier having a gain path and a phase path.

18. The transceiver of claim 11, wherein the APD circuit comprises a delay circuit and an amplifier.

19. The transceiver of claim 18, wherein the APD circuit further comprises a varactor.

20. The transceiver of claim 11, wherein the APD circuit comprises a plurality of delay paths each comprising a delay circuit, an amplifier, and a varactor.
